(19) United States
(12) Patent Application Publication
(10) Pub. No.: US 2025/0361646 A1
(43) Pub. Date: Nov. 27, 2025

(54) SINGLE CRYSTAL SILICON INGOT AND METHOD OF GROWING THE SAME

(71) Applicant: SK SILTRON CO., LTD., Gumi-si (KR)

(72) Inventors: Jong Min KANG, Gumi-si (KR); Byoung Woo PARK, Gumi-si (KR)

(21) Appl. No.: 19/293,348

(22) Filed: Aug. 7, 2025

Related U.S. Application Data
(63) Continuation of application No. 18/117,556, filed on Mar. 6, 2023.

(30) Foreign Application Priority Data
Feb. 7, 2023 (KR) 10-2023-0016281

(51) Int. Cl. C30B 15/22; C30B 29/06

(52) U.S. Cl. CPC C30B 15/22; C30B 29/06

(57) ABSTRACT

Disclosed is a method of growing a single crystal silicon ingot, including dipping a seed in a silicon melt, and sequentially growing a neck, a shoulder, and a body from the seed by pulling the seed, growing the neck includes growing a first neck part configured to have a cross-sectional area decreased from the seed, and growing a second neck part configured to have a constant cross-sectional area from the first neck part, and, in growing the first neck part, the seed is pulled at a speed equal to or less than 2.0 mm/min.

### CROSS-REFERENCE TO RELATED PATENT APPLICATIONS

This application is a continuation of U.S. patent application Ser. No. 18/117,556, filed Mar. 6, 2023, which claims the benefit of Korean Patent Application No. 10-2023-0016281, filed on Feb. 7, 2023, which is hereby incorporated by reference as if fully set forth herein.

### BACKGROUND OF THE INVENTION

### Field of the Invention

The present invention relates to a method of growing a single crystal silicon ingot using the Czochralski method and a single crystal silicon ingot grown thereby, and more particularly, to a method of controlling dislocations capable of occurring in a single crystal silicon ingot and a single crystal silicon ingot generated thereby.

### Discussion of the Related Art

In general, a silicon wafer is manufactured through a single crystal silicon ingot growth process of manufacturing a single crystal silicon ingot, a slicing process of acquiring silicon wafers having a thin disc shape by slicing the single crystal silicon ingot, a lapping process of removing damage to the wafer due to mechanical processing caused by the slicing process, a polishing process of polishing the surface of the wafer, and a cleaning process of smoothing the polished wafer and removing an abrasive or foreign substances from the wafer.

Among the above-described processes, in the single crystal silicon ingot growth process, a silicon (Si) melt may be manufactured by putting a polycrystalline material into a crucible and melting the polycrystalline material, a seed (i.e., a seed crystal) may be dipped in the Si melt, and the single crystal silicon ingot may be grown and pulled.

When the above seed is dipped in the Si melt, the Si melt having a high temperature may apply thermal impact to the seed, and thereby, dislocations may occur in the seed.

The above-described dislocation is a 2-dimensional defect, and the dislocation may be continuously transferred in a line shape, when the single crystal silicon ingot is grown from the seed, and may thus cause failure of the grown single crystal silicon ingot or a semiconductor wafer manufactured therefrom.

In order to prevent such growth of the dislocation, at an initial stage when the single crystal silicon ingot is grown by dipping the seed in the Si melt, a method of increasing the pulling speed of the seed may be used.

However, it takes time to grow a single crystal silicon ingot, used to manufacture semiconductor wafers having a large diameter, based on solidification of the Si melt, and therefore, there may be a limit in preventing occurrence of dislocations by increasing the pulling speed of the seed.

### SUMMARY OF THE INVENTION

Accordingly, the present invention is directed to a single crystal silicon ingot and a method of growing the same that substantially obviate one or more problems due to limitations and disadvantages of the related art.

An object of the present invention is to provide a method of controlling dislocations which occur and are transferred during growth of a single crystal silicon ingot.

To achieve these objects and other advantages and in accordance with the purpose of the invention, as embodied and broadly described herein, a method of growing a single crystal silicon ingot includes dipping a seed in a silicon melt, and sequentially growing a neck, a shoulder, and a body from the seed by pulling the seed, wherein growing the neck includes growing a first neck part configured to have a cross-sectional area decreased from the seed, and growing a second neck part configured to have a constant cross-sectional area from the first neck part, wherein, in growing the first neck part, the seed is pulled at a speed equal to or less than 2.0 mm/min.

In growing the second neck part, the seed may be pulled at a speed less than 5.0 mm/min.

A diameter of the first neck part may be 6 to 15 mm, and a diameter of the second neck part may be 4 to 6 mm.

The first neck part may be grown to a length of 10-40% of a total length of the neck, and the second neck part may be grown to a length of 60-90% of the total length of the neck.

A diameter of the seed may be 15 to 20 mm.

In growing the first neck part, an interface of the silicon melt with the first neck part may have a concave shape curved to protrude downwards.

In another aspect of the present invention, there is provided a single crystal silicon ingot grown by the above-described method, wherein specific resistance of a neck is 5-20 mΩ·cm.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a longitudinal-sectional view of an apparatus used in a method of growing a single crystal silicon ingot according to one embodiment of the present invention;

FIG. 2 is a schematic view showing the grown single crystal silicon ingot shown FIG. 1;

FIG. 3 is a schematic view showing a seed and a neck during a process of growing the single crystal silicon ingot;

FIG. 4 is a schematic view showing a process of growing the single crystal silicon ingot from a silicon melt; and

FIGS. 5A and 5B are schematic views showing growth of a dislocation depending on the shape of the interface between the silicon melt and the single crystal silicon ingot.

### DETAILED DESCRIPTION OF THE INVENTION

Hereinafter, embodiments will be described in detail so as to concretely describe the present invention and to help understanding of the present invention, with reference to the accompanying drawings.

However, the embodiments of the present invention may be variously modified and be implemented in various forms, and it will be understood that the scope of the present invention should not be interpreted as being limited to the embodiments set forth herein. The embodiments of the present invention are provided to make the description of the present invention thorough and to fully convey the scope of the present invention to those skilled in the art.

Further, relative terms, such as “first,” “second,” “above,” “below,” and the like when used herein, do not necessarily require or imply any physical or logical relationship between substances or elements indicated by the terms or a sequence or order thereof, and may be used only to distinguish one substance or element from another substance or element.

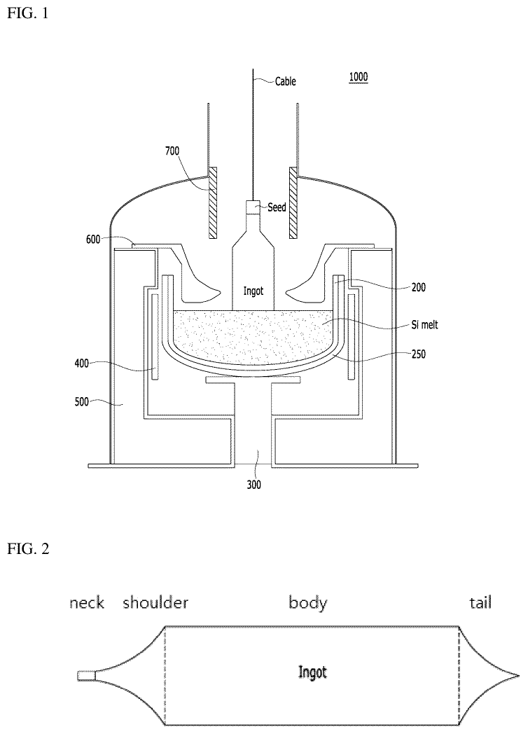

FIG. 1 is a longitudinal-sectional view of an apparatus used in a method of growing a single crystal silicon ingot according to one embodiment of the present invention.

As shown in this figure, an apparatus 1000 for growing a single crystal silicon ingot according to one embodiment of the present invention includes a chamber 100 having a space formed therein such that the single crystal silicon ingot is grown from a silicon (Si) melt in the space, a first crucible 200 formed of quartz and located in the inner area so as to receive the Si melt, a second crucible 250 formed of graphite and located in the outer area, a side heating unit 400 and a lower heating unit (not shown) configured to heat the first and second crucibles 200 and 250, a heat insulating member 500 provided outside the side heating unit 400 around the first and second crucibles 200 and 250, a heat shield 600 located above the first and second crucibles 200 and 250 and configured to block heat emitted from the side heating unit 400 towards the single crystal silicon ingot, a support member 300 located under the second crucible 250 so as to rotate and elevate the second crucible 250, and a water cooling pipe 700 fixed to the upper part of the inside of the chamber 100 and disposed around the single crystal silicon ingot grown and pulled from the Si melt.

The chamber 100 provides a space in which a series of designated processes of manufacturing the single crystal silicon ingot from the Si melt is performed. Here, the grown single crystal silicon ingot may have, for example, crystal orientation <100> or <111>.

The first and second crucibles 200 and 250 may be provided in the chamber 100 so as to receive the Si melt. The second crucible 250 may be divided into two pieces or four pieces in preparation for thermal expansion of the first crucible 200. For example, when the second crucible 250 is divided into two pieces, a gap is formed between the two pieces of the second crucible 250, and thus, the second crucible 250 may not be damaged even though the first crucible 200 in the second crucible 250 expands.

The heat insulating member 500 may be provided in the chamber 100 so as to prevent heat from the side heating unit 400 from being discharged to the outside. Although this embodiment describes the heat shield 600 disposed above the first and second crucibles 200 and 250 and the heat insulating member 500 disposed around the side surfaces of the first and second crucibles 200 and 250, a heat insulating member may also be disposed below the first and second crucibles 200 and 250.

The side heating unit 400 may melt polycrystalline silicon supplied to the inside of the first and second crucibles 200 and 250 into the Si melt, and current may be supplied to the side heating unit 400 from a current supply load (not shown).

A magnetic field generator (not shown) may be provided outside the chamber 100, and may apply a horizontal magnetic field to the first and second crucibles 200 and 250.

The support member 300 may be disposed at the center of the bottom surface of the first and second crucibles 200 and 250 so as to support, elevate, or rotate the first and second crucibles 200 and 250. A seed hung on a cable above the first and second crucibles 200 and 250 may be dipped in the Si melt, and the single crystal silicon ingot may be grown from the seed based on solidification of the Si melt.

Inert gas, for example, argon (Ar), may be supplied to the inside of the chamber 100 during the process of growing the single crystal silicon ingot, and in this embodiment, argon (Ar) may be supplied from an insert gas supplier (not shown).

FIG. 2 is a schematic view showing the grown single crystal silicon ingot shown FIG. 1.

The single crystal silicon ingot may include a neck grown from the seed and having a small diameter, a shoulder grown from the neck and having a rapidly increasing diameter, a body having an almost constant diameter and used as a material for semiconductor substrates through processes which will be described below, and a tail formed at the final stage of the single crystal silicon ingot growth process and having a rapidly decreasing diameter.

During such a single crystal silicon ingot growth process, various defects may occur, and the present invention is designed to remove dislocations resulting from a mismatch between lattice constants (the distances between atoms).

For example, screw dislocations may transition to jogged screw dislocations, and cross slip may occur depending on thermal history in which the single crystal silicon ingot is cooled.

The present invention is intended to control transfer of dislocations during growth of the neck, i.e., in the initial stage of the above-described single crystal silicon ingot growth process.

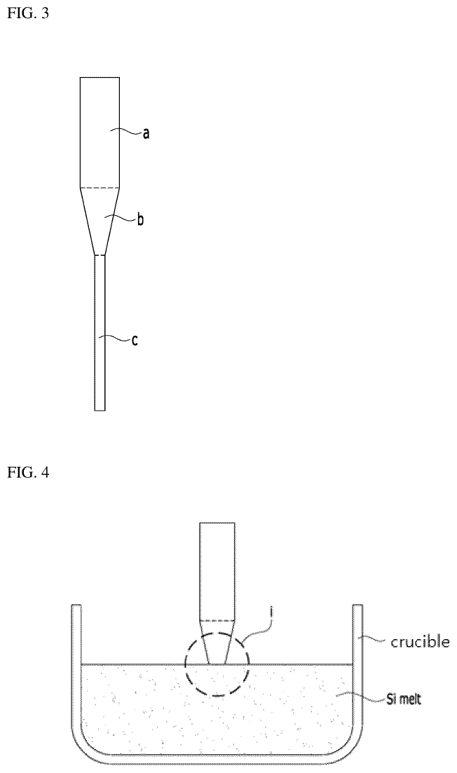

FIG. 3 is a schematic view showing the seed and the neck during the single crystal silicon ingot growth process.

FIG. 3 illustrates the seed a and the neck, and the neck is divided into a first neck part b and a second neck part c. The first neck part b has a diameter which gradually decreases from the diameter of the seed a, and the second neck part c has a diameter which is almost constant from the diameter of the lower end of the first neck part b.

The seed a is hung on the cable and is dipped in the Si melt, and the neck is grown from the seed a based on solidification of the Si melt after dipping. Here, the diameter or the cross-sectional area of the first neck part b may be gradually decreased from the diameter of the seed a, and the diameter or the cross-sectional area of the second neck part c may be almost constant from the diameter of the lower end of the first neck part b.

The diameter of the seed a may be, for example, 15 to 20 mm, the diameter of the first neck part b may be, for example, 6 to 15 mm, and the diameter of the second neck part c may be, for example, 4 to 6 mm.

Further, the length of the first neck part b in the vertical direction may be 10-40% of the total length of the neck, and the length of the second neck part c in the vertical direction may be 60-90% of the total length of the neck.

When the seed is dipped in the Si melt, thermal impact may be applied to the seed due to the high-temperature Si melt, and thereby, dislocations may occur in the seed. The dislocations may be transferred downwards, i.e., may be continuously transferred to the lower part of the growing single crystal silicon ingot, and particularly, when the dislocations are transferred to the body of the single crystal silicon ingot, quality of semiconductor substrates, which will be manufactured from the single crystal silicon ingot, may be deteriorated. Such dislocations may occur in the seed or the first neck part, which will be described below.

For this purpose, transfer of the dislocations to the body of the single crystal silicon ingot may be prevented by controlling the growth speed of the neck of the single crystal silicon ingot.

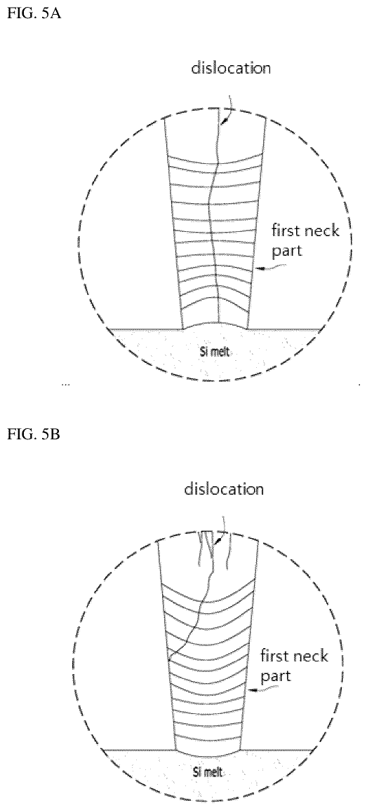

FIG. 4 is a schematic view showing the process of growing the single crystal silicon ingot from the Si melt, and FIGS. 5A and 5B are schematic views showing growth of a dislocation depending on the shape of the interface between the Si melt and the single crystal silicon ingot, i.e., are enlarged views of region i of FIG. 4.

When a single crystal silicon ingot is grown by dipping a seed in a silicon (Si) melt, the interface between the Si melt and the single crystal silicon ingot, i.e., the interface between the first neck part, which is a part of the single crystal silicon ingot grown based on solidification of the Si melt, and the Si melt is not flat, and may have a convex shape curved to protrude upwards, as shown in FIG. 5A, or may have a concave shape curved to protrude downwards, as shown in FIG. 5B.

Here, when the interface between the Si melt and the single crystal silicon ingot has a convex shape curved to protrude upwards, as shown in a comparative example of FIG. 5A, a dislocation occurring in the seed may be continuously transferred downwards. On the other hand, when the interface between the Si melt and the single crystal silicon ingot has a concave shape curved to protrude downwards, as shown in an example of FIG. 5B, a dislocation occurring in the seed may be transferred sideways, and thus may not be transmitted to a body which will be grown in succession to the lower part of the seed.

Therefore, it is necessary to form the interface between the Si melt and the single crystal silicon ingot so as to have a concave shape curved to protrude downwards, during growth of the single crystal silicon ingot, particularly, the first neck part. For this purpose, in the method of growing the single crystal silicon ingot according to one embodiment of the present invention, the interface between the Si melt and the single crystal silicon ingot is controlled so as to have such a concave shape curved to protrude downwards by controlling the pulling speed of the seed in a first neck part growth stage.

In the first neck part growth stage, the pulling speed of the seed is controlled not to be too low because the diameter or the cross-sectional area of first neck part should be gradually decreased, but, when the pulling speed of the seed is too high, the interface between the Si melt and the single crystal silicon ingot has a convex shape curved to protrude upwards, and thus, dislocations may be transferred to the body of the growing single crystal silicon ingot.

Therefore, in this embodiment, by controlling the seed at a pulling speed equal to or less than 2.0 mm/min in the first neck part growth stage, the interface between the Si melt and the single crystal silicon ingot has a concave shape curved to protrude downwards while gradually decreasing the diameter or the cross-sectional area of the first neck part, and thereby, the above-described dislocations are not transferred to the body of the single crystal silicon ingot.

Further, when the second neck part having a constant diameter or cross-sectional area is grown after growth of the first neck part has been completed, the pulling speed of the seed may be increased, particularly, to less than 5.0 mm/min.

The diameter or cross-sectional area of the second neck part may remain constant and the second neck part may be rapidly pulled by increasing the pulling speed of the second neck part as above.

When the pulling speed of the second neck part is equal to or greater than 5.0 mm/min, the diameter or radius of the second neck part is excessively decreased and thus the second neck part may have difficulty supporting the load of the body. When the pulling speed of the second neck part is not increased compared to the pulling speed of the first neck part, a process time may be excessively elongated, and dislocations may additionally occur in the second neck part.

In Table 1 below, Examples 1, 2 and 3 represent whether or not dislocations are transferred depending on the pulling speed of the seed in the method according to the present invention, and Comparative Examples 1, 2 and 3 represent whether or not dislocations are transferred depending on the pulling speed of the seed different from the pulling speed in the method according to the present invention.

TABLE 1

| | | Pulling | Whether or |
|---|---|---|---|
| | Diameter | speed | not dislocations |
| | (mm) | (mm/min) | are transferred |
| Example 1 | 6-15 | 1.8 | No |
| | 5 | 3 | |
| Example 2 | 6-15 | 2 | No |
| | 5 | 3 | |
| Example 3 | 6-15 | 1.5 | No |
| | 5 | 4 | |
| Comparative | 6-15 | 2.5 | Yes |
| example 1 | 5 | 4 | |
| Comparative | 6-15 | 3 | Yes |
| example 2 | 5 | 3 | |
| Comparative | 6-15 | 3 | Yes |
| example 3 | 5 | 2.5 | |

In Table 1, the diameter of 6-15 mm indicates the diameter of the first neck part of the above-described single crystal silicon ingot, and the diameter of 5 mm indicates the diameter of the second neck part.

As set forth in Table 1, it may be confirmed that, when the pulling speed of the first neck part is equal to or less than 2 mm/min as in Examples 1, 2 and 3, dislocations are not transferred to the second neck part, the shoulder or the body formed thereunder, and, when the pulling speed of the first neck part exceeds 2 mm/min as in Comparative Examples 1, 2 and 3, dislocations are transferred to the second neck part, the shoulder or the body formed thereunder.

Further, the single crystal silicon ingot grown through the above-described pulling method may have, for example, crystal orientation <100> or <111>. In addition, the grown single crystal silicon ingot, particularly, the neck of the grown single crystal silicon ingot, may have specific resistance of 5-20 mΩ·cm.

According to the above-described method and the single crystal silicon ingot manufactured thereby, the interface between the Si melt and the first neck part is controlled to have a concave shape curved to protrude downwards by controlling the pulling speed of the seed during growth of the first neck part, and thus, dislocations occurring due to thermal impact to the seed dipped in the Si melt are not transferred to the body of the single crystal silicon ingot and disappear, thereby being capable of improving the quality of the grown single crystal silicon ingot.

As is apparent from the above description, in a method of growing a single crystal silicon ingot and a single crystal silicon manufactured thereby according to the present invention, the interface between a Si melt and a first neck part is controlled to have a concave shape curved to protrude downwards by controlling the pulling speed of a seed during growth of the first neck part, and thus, dislocations occurring due to thermal impact to the seed dipped in the Si melt are not transferred to a body of the single crystal silicon ingot and disappear, thereby being capable of improving the quality of the grown single crystal silicon ingot.

While the embodiments of the present invention has been explained with reference to the accompanying drawings, the present invention is not limited to these embodiments, and it will be apparent to those skilled in the art that various modifications and variations can be made in the present invention without departing from the spirit or scope of the invention. Therefore, the embodiments disclosed in the present invention is for the purpose of describing the invention only and is not intended to limit the scope of the invention, and the scope of the invention is not limited by the embodiments. Accordingly, it will be understood that the above-described embodiments are only exemplary and are not intended to limit the present invention. The scope of the present invention is defined not by the detailed description, but by the claims and their equivalents, and all variations within the scope of the claims and their equivalents are to be construed as being included in the present invention.

What is claimed is:

1. A method of growing a single crystal silicon ingot, comprising:
dipping a seed in a silicon melt; and
sequentially growing a neck, a shoulder, and a body from the seed by pulling the seed,
wherein growing the neck comprises growing a first neck part configured to have a cross-sectional area decreased from the seed, and growing a second neck part configured to have a constant cross-sectional area from the first neck part, and
wherein specific resistance of a neck is 5-20 mΩ·cm.

2. The method according to claim 1, wherein a diameter of the seed is 15 mm to 20 mm.

3. The method according to claim 1, wherein a diameter of the first neck part is 6 mm to 15 mm and a diameter of the second neck part is 4 mm to 6 mm.

4. The method according to claim 1, wherein the first neck part is grown to a length of 10% to 40% of a total length of the neck, and the second neck part is grown to a length of 60% to 90% of the total length of the neck.

5. The method according to claim 1, wherein, in growing the first neck part, an interface of the silicon melt with the first neck part has a concave shape curved to protrude downwards.

6. The method according to claim 1, wherein, in growing the first neck part, the seed is pulled at a speed equal to or less than 2.0 mm/min.

7. The method according to claim 6, wherein, in growing the first neck part, the seed is pulled at a speed 1.8 mm/min and a diameter of the first neck part is 6 mm to 15 mm.

8. The method according to claim 7, wherein, in growing the second neck part, the seed is pulled at a speed 3 mm/min and a diameter of the second neck part is 5 mm.

9. The method according to claim 6, wherein, in growing the first neck part, the seed is pulled at a speed 2 mm/min and a diameter of the first neck part is 6 mm to 15 mm.

10. The method according to claim 9, wherein, in growing the second neck part, the seed is pulled at a speed 3 mm/min and a diameter of the second neck part is 5 mm.

11. The method according to claim 6, wherein, in growing the first neck part, the seed is pulled at a speed 1.5 mm/min and a diameter of the first neck part is 6 mm to 15 mm.

12. The method according to claim 11, wherein, in growing the second neck part, the seed is pulled at a speed 4 mm/min and a diameter of the second neck part is 5 mm.

13. The method according to claim 1, wherein a pulling speed of the second neck part is increased compared to a pulling speed of the first neck part.

14. The method according to claim 13, wherein, in growing the second neck part. the seed is pulled at a speed less than 5.0 mm/min.

15. The method according to claim 1. wherein the single crystal silicon ingot has crystal orientation <100> or <111>.
